(19) United States
(12) Patent Application Publication
(10) Pub. No.: US 2013/0244388 A1
(43) Pub. Date: Sep. 19, 2013

(54) METHODS FOR FABRICATING INTEGRATED CIRCUITS WITH REDUCED ELECTRICAL PARAMETER VARIATION

(71) Applicants: Thilo Scheiper, Dresden (DE); Stefan Flachowsky, Dresden (DE); Shesh Mani Pandey, Dresden (DE)

(72) Inventors: Thilo Scheiper, Dresden (DE); Stefan Flachowsky, Dresden (DE); Shesh Mani Pandey, Dresden (DE)

(73) Assignee: GLOBALFOUNDRIES INC., Grand Cayman (KY)

(21) Appl. No.: 13/421,604

(22) Filed: Mar. 15, 2012

(51) Int. Cl. H01L 21/336

(52) U.S. Cl. 438/285; 438/302; 257/E21.409

(57) ABSTRACT

Methods for fabricating integrated circuits are provided. In an embodiment, a method for fabricating an integrated circuit includes forming a gate stack on a semiconductor substrate. In the method, a first halo implantation is performed on the semiconductor substrate with a first dose of dopant ions to form first halo regions therein. A second halo spacer is formed around the gate stack. Then a second halo implantation is performed on the semiconductor substrate with a second dose of dopant ions to form second halo regions therein.

### TECHNICAL FIELD

The present disclosure generally relates to methods for fabricating integrated circuits, and more particularly relates to methods for fabricating integrated circuits with reduced electrical parameter variation.

### BACKGROUND

The majority of present day integrated circuits (ICs) are implemented by using a plurality of interconnected field effect transistors. The complexity of ICs and the number of devices incorporated in ICs are continually increasing. As the number of devices in an IC increases, the size of individual devices decreases. As the semiconductor industry moves to smaller minimum feature sizes, the performance of individual devices degrades as the result of scaling. As new generations of integrated circuits and the transistors that are used to implement those integrated circuits are designed, technologists must rely heavily on non-conventional processes to boost device performance.

Process variation and electrical device parameter variation is a severe problem in current and future technologies due to the extremely small dimensions used in 32 nanometer (nm), 28 nm, and smaller generations. For example, a variation in spacer thickness of a few nanometers, e.g., a 15 nm thickness with a ±1 nm variation, can cause a threshold voltage variation of 150 mV. Such a threshold voltage variation is much too large for a device with a targeted threshold voltage of 180 mV. The leakage current of such a device would be magnitudes of order higher that what is typically allowed in product specifications.

Conventional methods to reduce threshold voltage variation attempt to reduce process variation by using stable processes. For instance, such processes may form spacers with a deposition process that is extremely conformal over the wafer both in dense areas and in homogenous areas. An iRAD spacer, which is a very homogenous spacer deposited by chemical vapor deposition (CVD), has sidewalls with constant thicknesses independent of the surrounding pattern density, which may include single or double pitch structures. As a result, variation is reduced compared to spacers formed by less conformal CVD processes which exhibit thicker layers in less dense areas (i.e., in less conformal processes spacers formed around double pitch structures are thicker than those formed around single pitch structures). It has been determined that the use of extremely conformal spacers may control spacer thickness variation and reduce threshold variation by a factor of two. However, typical processes used to form extremely conformal spacers incorporate oxygen. For use with high-k/metal-gate technologies, the incorporation of oxygen causes a threshold voltage shift. For narrow width devices, the threshold voltage shift is severe and causes a width dependent threshold voltage trend which is not suitable for circuit integration.

Accordingly, it is desirable to provide integrated circuits and methods for fabricating integrated circuits with reduced electrical parameter variation, including without limitation, reduced threshold voltage variation or reduced drive current variation. Furthermore, other desirable features and characteristics will become apparent from the subsequent detailed description and the appended claims, taken in conjunction with the accompanying drawings and the foregoing technical field and background.

### BRIEF SUMMARY

Methods for fabricating integrated circuits are provided. In accordance with one embodiment, a method for fabricating an integrated circuit includes forming a gate stack on a semiconductor substrate. In the method, a first halo implantation is performed on the semiconductor substrate with a first dose of dopant ions to form first halo regions therein. A second halo spacer is formed around the gate stack. Then a second halo implantation is performed on the semiconductor substrate with a second dose of dopant ions to form second halo regions therein.

In another embodiment, a method for reducing electrical parameter variation in an integrated circuit includes providing a semiconductor substrate with a gate stack formed thereon and with first halo regions formed therein. A halo spacer is formed around the gate stack. Then a self-aligned halo implantation is performed on the semiconductor substrate to form second halo regions therein.

In accordance with another embodiment, a method for fabricating an integrated circuit includes forming a gate stack on a semiconductor substrate. A first halo spacer is formed around the gate stack on the semiconductor substrate. A first halo implantation is performed on the semiconductor substrate to form first halo regions therein. Also, an extension implantation is performed on the semiconductor substrate to form extension regions therein. A second halo spacer is formed around the gate stack, and a second halo implantation is performed on the semiconductor substrate to form second halo regions therein. The method includes performing a source/drain implantation on the semiconductor substrate to form source/drain regions. The first halo regions, extension regions, second halo regions, and source/drain regions are then annealed.

### BRIEF DESCRIPTION OF THE DRAWINGS

Embodiments of the methods for fabricating integrated circuits will hereinafter be described in conjunction with the following drawing figures, wherein like numerals denote like elements, and wherein:

FIGS. 1-5 illustrate, in cross section, method steps for fabricating an integrated circuit in accordance with various embodiments herein.

### DETAILED DESCRIPTION

The following detailed description is merely exemplary in nature and is not intended to limit the methods for fabricating integrated circuits as claimed herein. Furthermore, there is no intention to be bound by any theory presented in the preceding background or the following detailed description. Also, additional components may be included in the integrated circuits, and additional processes may be included in the fabrication methods but are not described herein for purposes of clarity. For the purposes of explanation, numerous specific details are set forth in order to provide a thorough understanding of exemplary embodiments. It should be apparent, however, that exemplary embodiments may be practiced without these specific details or with an equivalent arrangement.

Methods for fabricating integrated circuits are contemplated herein. The methods reduce electrical parameter variation, such as variation resulting from variable spacer thicknesses. Rather than focusing on reducing spacer thickness variability, the methods herein use multiple halo implantations to inhibit electrical parameter variation that typically results from spacer thickness variation in conventional fabrication methods. In the contemplated methods, two halo implantations are performed, one before forming the source/drain spacer and one after forming the source/drain spacer. In certain embodiments, the second halo implantation is performed with a higher dose than the first halo implantation. However, the second halo implantation may be performed with a dose equal to or less than the first halo implantation as desired. As a result of the two-stage halo implantation, the effects of spacer thickness variation on electrical parameter variation are reduced.

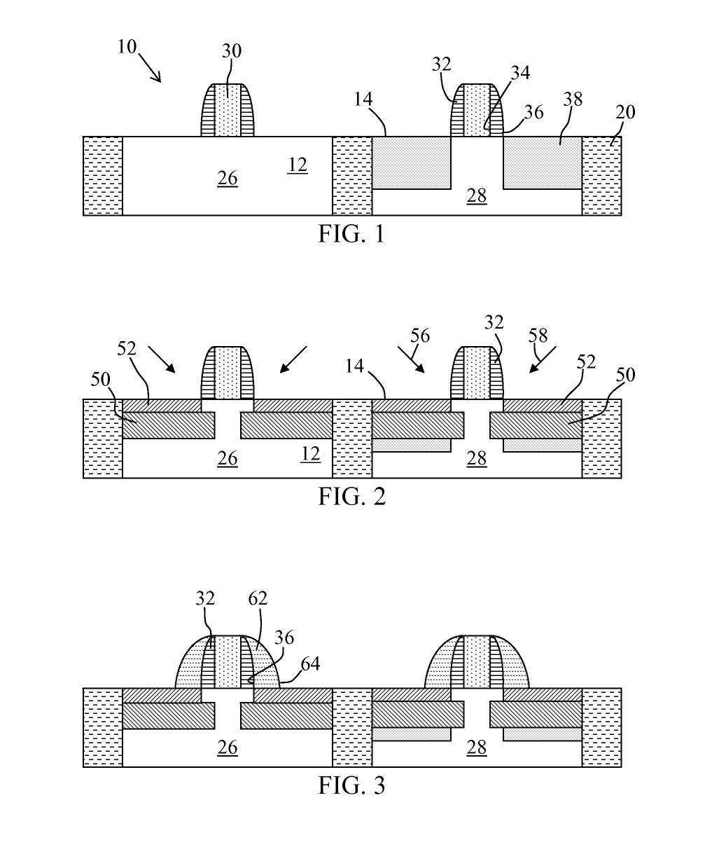

Referring to FIG. 1, a method for fabricating an integrated circuit 10, in accordance with an exemplary embodiment, includes providing a semiconductor substrate 12 with a surface 14. The semiconductor substrate 12 may be bulk silicon or a silicon on insulator (SOI) wafer. The silicon on insulator (SOI) wafer includes a silicon-containing material layer overlying a silicon oxide layer. In certain embodiments, the semiconductor substrate may be considered to include only the semiconductor layer. While the semiconductor layer is preferably a silicon material, the term “silicon material” is used herein to encompass the relatively pure silicon materials typically used in the semiconductor industry as well as silicon admixed with other elements. Alternatively, the semiconductor layer can be realized as germanium, gallium arsenide, and the like.

In an exemplary embodiment, isolation regions 20, such as shallow trench isolation (STI) regions, are formed in the semiconductor substrate 12 and define semiconductor regions 26 and 28. A gate stack 30, including a gate oxide and gate, is formed on the semiconductor substrate 12 in each semiconductor region 26, 28 through typical processing, such as deposition and lithography steps. The gates stack 30 may be a final gate stack, or a dummy gate stack used in a gate/last gate replacement process.

As shown in FIG. 1, a spacer 32 is formed around the gate stack 24. An exemplary spacer 32 is made of nitride or oxide with a maximum thickness (measured from surface 34 to surface 36) of about 8 nanometers (nm) to about 16 nm. As shown in FIG. 1, an eSiGe region 38 may be formed as a stressor in the PFET region (which may be formed in semiconductor region 26 or 28) through etching a cavity in the semiconductor substrate 12 around gate stack 24 and depositing SiGe therein.

In FIG. 2, halo regions 50 and source/drain extension regions 52 are formed in the semiconductor substrate 12 through ion implantation using the spacer 32 as a mask. In an exemplary embodiment, semiconductor region 26 is masked and the halo region 50 is formed in semiconductor region 28 by implanting dopant ions into the semiconductor substrate 12. The halo implantation is performed at a first angle and second angle to the surface 14 of the semiconductor substrate 12, such as about 25° to about 35° as indicated by arrows 56 and 58, to allow the halo region 50 to be formed and to extend under the spacer 32. The halo region 50 may be formed with dopant ions such as B+, BF 2+, As+, Sb+, or P+.

The extension region 52 is then formed by implanting dopant ions into the semiconductor substrate 12 while using the spacer 32 as a mask. Shallow (approximately 10 nm to approximately 30 nm) source/drain extension regions 52 may be formed with dopant ions such as B+, BF 2+, As+, Sb+, or P+. The masked semiconductor region 26 is then unmasked and semiconductor region 28 is masked before the halo regions 50 and extension regions 52 are formed in semiconductor region 28. The masks are then removed. During the implantation processes, the halo regions 50 are implanted with a dopant that is opposite in conductivity type to the dopant of the extensions 52. For example, when the halo regions 50 are implanted with an n-type dopant, such as arsenic (As), phosphorous (P), or antimony (Sb), the extension regions 52 are implanted with a p-type dopant such as boron (B).

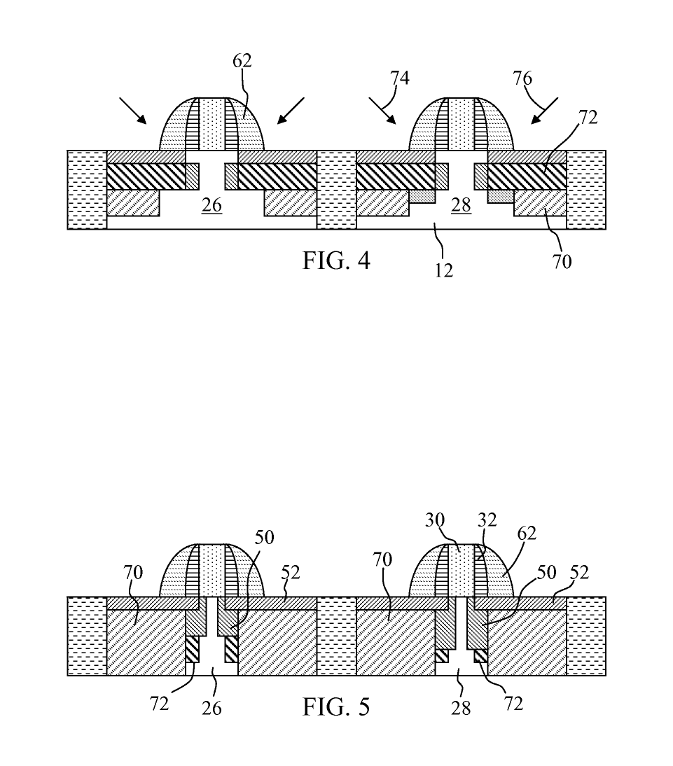

As shown in FIG. 3, a spacer 62 is formed around the spacer 32. An exemplary spacer 62 is made of nitride with a maximum thickness (measured from surface 36 to surface 64) of about 18 nm to about 30 nm. After formation of the spacer 62, semiconductor region 26 is masked. In FIG. 4 a source/drain implantation is performed to create source/drain regions 70 in semiconductor region 28 using the spacer 62 as a mask. The source/drain implantation may be performed with dopant ions such as B+, BF 2+, As+, Sb+, or P+. Then, a second or source/drain halo implantation is performed to form a second or source/drain halo region 72. The second halo implantation is self-aligned with the spacer 62. During the second halo implantation, ions such as B+, BF 2+, As+, Sb+, or P+are implanted at angles of between about 25° to about 35° to the surface 14 of the semiconductor substrate 12 as represented by arrows 74 and 76.

For the second implantation processes, the source/drain regions 70 are implanted with dopant ions that are of the same conductivity type as the dopant ions used to form the extensions 52. Further, the second halo regions 72 are implanted with dopant ions that share the same conductivity type as the dopant ions which form the first halo regions 50 and are opposite the conductivity type of the dopant ions used in extension and source/drain implantations. In an exemplary embodiment, the second halo implantation is performed with a higher dose as compared to the first halo implantation.

For instance, in an exemplary process, the first halo implantation may be performed with arsenic ions at an energy between about 35 KeV to about 50 KeV, and at a dose between about 3E13 to about 6E13 atoms/cm², while the second halo implantation may be performed with arsenic ions at an energy between about 40 KeV to about 60 KeV, and at a dose between about 4E13 to about 8E13 atoms/cm². Generally, the dose of the second halo implantation should be about 1.5 to about 3 times greater, such as about 2 times, greater than the dose of the first halo implantation. Further, the energy in the second halo implantation should be about 5% to about 20%, such as about 10%, greater than the energy used in the first halo implantation.

FIG. 5 illustrates that the method includes annealing the implantation regions to activate the dopants. During annealing, the various single doped implantation regions diffuse under the spacers 32 and 62. In an exemplary embodiment, a spike annealing or rapid thermal annealing (RTA) process such as at a maximum temperature of about 1000° C. to about 1100° C. for 2 seconds, with a ramp rate of about 75 Kelvin/second. In FIG. 5, the source/drain regions 70 in semiconductor regions 26 and 28 extend deeper from the extension region 52 after annealing, the first halo regions 50 and the second halo regions 72 extend further under the gate stacks 30 or spacers 32, respectively, and the extension regions 52 extend under the spacers 32.

Thereafter, typical processing is performed to complete the transistors and to form the integrated circuit. For instance, silicide contacts may be formed on the source/drain regions and on the gate stacks. Other conventional processing is performed to complete the integrated circuit 10.

Transistors formed in accordance with the methods herein exhibit a changed doping profile as compared to conventionally fabricated transistors. Specifically, due to a higher amount of counterdoping from the second halo implantation, the junction in the transistor as fabricated herein is shallower and steeper than conventional junctions. These properties are beneficial in terms of short channel effect. Further, threshold voltage variation resulting from spacer thickness variation is significantly reduced in comparison to conventionally-fabricated transistors. For example, for a spacer 62 having a 15 nm thickness, a variation of +1 nm or −1 nm in spacer thickness has been found to result in a threshold voltage variation of 150 mV for conventional transistors. On the other hand, transistors fabricated according to the methods herein, with spacers 62 having the same thickness variation, exhibit threshold voltage variation of only 25 mV, i.e., a reduction in threshold voltage variation by a factor of 6. This significant improvement makes the integrated circuit more stable and robust against process variation. Variation in other electrical parameters, such as drive current, can be reduced additionally or alternatively.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method for fabricating an integrated circuit comprising:
forming a gate stack on a semiconductor substrate;
performing a first halo implantation on the semiconductor substrate with a first dose of dopant ions to form first halo regions therein;
forming a second halo spacer around the gate stack; and
performing a second halo implantation on the semiconductor substrate with a second dose of dopant ions to form second halo regions therein.

2. The method of claim 1 wherein the second dose is about two times greater than the first dose.

3. The method of claim 1 further comprising forming a first halo spacer around the gate stack on the semiconductor substrate before performing the first halo implantation.

4. The method of claim 1 further comprising performing an extension implantation on the semiconductor substrate to form extension regions therein before forming the second halo spacer.

5. The method of claim 4 further comprising performing a source/drain implantation on the semiconductor substrate to form source/drain regions after forming the second halo spacer.

6. The method of claim 5 further comprising annealing the first halo regions, extension regions, second halo regions, and source/drain regions.

7. The method of claim 5 further comprising annealing the first halo regions, extension regions, second halo regions, and source/drain regions through a rapid thermal annealing process at a maximum temperature of about 1000° C. to about 1100° C. for a duration of about 2 seconds with a ramp rate of about 75 K/second.

8. The method of claim 5 further comprising:
etching cavities in the semiconductor substrate around the gate stack; and
forming eSiGe regions in the cavities before performing the first halo implantation.

9. The method of claim 1 wherein forming the first spacer comprises forming an oxide or nitride spacer having a thickness of about 8 nm to about 16 nm, and wherein forming the second halo spacer comprises forming a nitride spacer having a thickness of about 18 nm to about 30 nm.

10. The method of 1 wherein performing the second halo implantation comprises performing the second halo implantation at an angle of about 25° to about 35°.

11. A method for reducing electrical parameter variation in an integrated circuit comprising:
providing a semiconductor substrate with a gate stack formed thereon and with first halo regions formed therein;
forming a halo spacer around the gate stack; and
performing a self-aligned halo implantation on the semiconductor substrate to form second halo regions therein.

12. The method of claim 11 wherein providing comprises:
forming the gate stack on the semiconductor substrate;
forming a first halo spacer around the gate stack on the semiconductor substrate; and
performing a first halo implantation to form the first halo regions therein.

13. The method of claim 12 wherein performing the first halo implantation comprises implanting a first does of dopant ions into the semiconductor substrate, wherein performing the self-aligned halo implantation comprises implanting a second does of dopant ions into the semiconductor substrate, and wherein the second dose is greater than the first dose.

14. The method of claim 11 wherein providing comprises providing the semiconductor substrate with the gate stack formed thereon, with first halo regions formed therein, and with extensions formed therein.

15. The method of claim 14 wherein providing comprising performing an extension implantation on the semiconductor substrate to form the extension regions therein.

16. The method of claim 14 further comprising performing a source/drain implantation on the semiconductor substrate to form source/drain regions after forming the halo spacer.

17. The method of claim 16 further comprising annealing the first halo regions, extension regions, second halo regions, and source/drain regions.

18. The method of claim 17 further comprising annealing the first halo regions, extension regions, second halo regions, and source/drain regions through a rapid thermal annealing process at a maximum temperature of about 1000° C. to about 1100° C. for a duration of about 2 seconds with a ramp rate of about 75 K/second.

19. The method of claim 11 wherein forming the halo spacer comprises forming a nitride spacer having a thickness of about 18 nm to about 30 nm, and wherein performing the self-aligned halo implantation comprises performing the second halo implantation at an angle of about 25° to about 35°.

20. A method for fabricating an integrated circuit comprising:
forming a gate stack on a semiconductor substrate;
forming a first halo spacer around the gate stack on the semiconductor substrate;
performing a first halo implantation on the semiconductor substrate to form first halo regions therein;
performing an extension implantation on the semiconductor substrate to form extension regions therein;
forming a second halo spacer around the gate stack;
performing a second halo implantation on the semiconductor substrate to form second halo regions therein;
performing a source/drain implantation on the semiconductor substrate to form source/drain regions; and
annealing the first halo regions, extension regions, second halo regions, and source/drain regions.
